(19) United States
(12) Patent Application Publication
(10) Pub. No.: US 2018/0254363 A1
(43) Pub. Date: Sep. 6, 2018

(54) SEMICONDUCTOR DEVICES HAVING MATRIX-EMBEDDED NANO-STRUCTURED MATERIALS

(71) Applicant: The Board of Regents of the University of Oklahoma, Norman, OK (US)

(72) Inventor: Zhisheng Shi, Norman, OK (US)

(21) Appl. No.: 15/755,941

(22) PCT Filed: Aug. 31, 2016
(86) PCT No.: PCT/US16/49734

§ 371 Date: Feb. 27, 2018

Related U.S. Application Data
(60) Provisional application No. 62/212,260, filed on Aug. 31, 2015.

(51) Int. Cl. H01L 31/0328; H01L 31/0352; H01L 31/0384

(52) U.S. Cl. CPC H01L 31/0328; H01L 31/03845; H01L 31/035218

(57) ABSTRACT

A structure having a bulk crystalline matrix material and a plurality of nanoscale crystallites embedded within the bulk crystalline matrix material. The bulk crystalline matrix material and the nanoscale crystallites comprise a semiconductor material having the same chemical composition. The nanoscale crystallites are spatially distributed throughout substantially the entire bulk crystalline matrix material.

### CROSS REFERENCE TO RELATED APPLICATIONS/INCORPORATION BY REFERENCE STATEMENT

The present patent application incorporates by reference the entire provisional patent application identified by U.S. Ser. No. 62/212,260, filed on Aug. 31, 2015, and claims priority thereto under 35 U.S.C. 119(e).

### STATEMENT REGARDING FEDERALLY SPONSORED RESEARCH AND DEVELOPMENT

This invention was made with government support under W911NF1410312 awarded by the Army Research Office. The government has certain rights in the invention.

### BACKGROUND

Semiconductor quantum dots (QDs), especially colloidal QDs (CQDs), have been considered as promising candidates for the fabrication of optoelectronic devices such as solar cells and detectors. The main advantages of CQDs include: high material quality produced by inexpensive wet-chemical processes, high absorption coefficient and tunable band gap due to quantum effect, and multiple exciton generation⁸ that could improve the light-to-current conversion efficiencies.

Lead-salt semiconductor (such as lead(II) sulfide (PbS) and lead selenide (PbSe)) QDs, particularly CQDs, have been considered as promising candidates.¹⁻⁷ The main advantages of Pb-salt CQDs include: high material quality produced by inexpensive wet-chemical processes, high absorption coefficient and tunable band gap due to quantum effect, and multiple exciton generation⁸ that could overcome the efficiency limit of single energy gap and thus improve the light-to-current power conversion efficiencies (PCEs). PCEs of 8.55% with PbS CQDs⁹ and 6.2% with PbSe CQDs¹⁰ have been demonstrated in the prior art. Over the past couple of years, however, the interest in Pb-salt QD solar materials has been suppressed by the rapid development of perovskites solar materials,¹¹⁻¹² with the best reported PCE over 20%.¹³

The key challenge for the development of CQD devices is inefficient extraction of photon-induced carriers, leading to low signal current. The root cause of this issue is that CQD thin film is constructed from a large number of nano-scaled QDs. Currently-available quantum-dot (QD) solar cells suffer from low short circuit current density (J_{sc}) due to the interfaces between the QDs, which restrict further enhancement of PCE. Although the crystal quality of each individual QD may be very high, loss processes may be introduced because of the large ratio of interface/volume that makes CQD films prone to high trap state densities if surfaces are imperfectly passivated¹⁴. Interfaces comprised of a ligand, usually organic ligand, are necessary to separate individual CQDs and passivate the CQD surface, which in turn may hinder efficient carrier transport within the film. In addition, high quality CQD thin film synthesis may require a ligand exchange process not capable of being performed at normal ambient atmosphere.

Chemical bath deposition (CBD) has also been used to fabricate Pb-salt QD film. ¹⁵⁻¹⁷ In comparison to CQD film, CBD QD film can be directly deposited at ambient atmosphere onto a substrate with very good adhesion. Therefore, it offers a very low-cost, scalable, industrially-viable wet-chemical-growth method. Standard IC fabrication processes including standard wet processes could be used on CBD QD films, which is advantageous over CQD and perovskites materials. However, the CBD QD size homogeneity is inferior to its CQD counterpart.¹⁸

### BRIEF DESCRIPTION OF THE DRAWINGS

Several embodiments of the present disclosure are hereby illustrated in the appended drawings. It is to be noted however, that the appended drawings only illustrate several typical embodiments and are therefore not intended to be considered limiting of the scope of the present disclosure. Further, in the appended drawings, like or identical reference numerals or letters may be used to identify common or similar elements and not all such elements may be so numbered. The figures are not necessarily to scale and certain features and certain views of the figures may be shown as exaggerated in scale or in schematic in the interest of clarity and conciseness.

FIG. 1(a) is a schematic diagram of an exemplary p-n junction solar cell structure with an exemplary structure in accordance with the present disclosure.

FIG. 1(b) is an energy level diagram of a solar cell including a structure in accordance with the present disclosure.

FIG. 2(a) is a typical SEM image of surface morphology of PbS quantum dots (QDs).

FIG. 2(b) is an exemplary cross-sectional view of PbS QDs in PbS matrix.

FIG. 3(a) is a graph of a PL emission spectra of three 0.15 μm thick PbS QD samples.

FIG. 3(b) is a graph of a PL emission spectra of a 0.4 μm thick PbS quantum dot matrix (QDM) film. All samples from which the graphs of FIGS. 3(a) and 3(b) were derived were grown on glass substrate. FIGS. 3(a) and 3(b) also show Gaussian curve fitting.

FIG. 4(a) is a graph of transmission of 150 nm thick PbS QDs and PbS QDM.

FIG. 4(b) is a graph of absorbance vs. hv plot for PbS QDM.

FIG. 4(c) is a graph of (αhv)² vs. hv plots for PbS QDs films.

FIG. 4(d) is a (αdhv)² vs. hv plot for PbS QDM.

FIG. 4(e) is another (αdhv)² vs. hv plot for PbS QDM.

FIG. 5(a) is a graph depicting J-V curves for PbS QD in PbS matrix solar cell in dark and AM1.5 G illumination.

FIG. 5(b) is a graph depicting solar cell performance.

FIG. 6 shows a J_{sc}-V_{oc} map for typical photovoltaic solar.^{9, 10, 13, 17, 31-42}

### DETAILED DESCRIPTION

The present disclosure is directed to semiconductor devices constructed with a bulk material matrix containing embedded nanometer (i.e., nanometer scale or nanoscale) crystallite structures, such as quantum dots (QDs), having either a homogeneous or inhomogeneous arrangement (i.e., a non-uniform spatial distribution) in the bulk material matrix. The bulk material matrix has the same semiconductor chemical composition (e.g., PbS or PbSe, or others described elsewhere herein) as the nanometer scale crystallite structures embedded therein. Here bulk material matrix is defined as a crystallite material comprising crystallites that on average are significantly larger (e.g., by a factor of at least 10) than the nanometer scale crystallites contained therein. The bulk material matrix can comprise micrometer scale (microscale) crystallites or can comprise a continuous single crystalline material. When the bulk material matrix comprises a plurality of microscale crystallites, each microscale crystallite further comprises a plurality of the nanoscale crystallites (e.g., QDs) embedded therein. In at least one embodiment, the nanometer crystallite structures (i.e., the QDs) are grown in the bulk material matrix as the matrix is deposited by a growth method such as, but not limited to, chemical bath deposition (CBD). Where used herein, the term “crystallite” refers to an individual perfect crystal or a region of regular crystalline structure in the substance of a material. Where used herein the term nanometer crystal, nanometer crystallite, nanoscale crystallite, nanocrystal, nanocrystallite, or quantum dot refers to a crystallite having a nanoscale size. Where used herein the term micrometer crystal, micrometer crystallite, microscale crystallite, microcrystal, or microcrystallite refers to a crystallite having a microscale size. Where used herein the term nanometer scale or nanoscale refers to an object having a size in a range of about 1 nm to about 100 nm. Where used herein the term micrometer scale or microscale refers to an object having a size of in a range about 100 nm to about 10 μm.

Semiconductor devices as presently disclosed have improved carrier transport as compared to conventional QD films. Applications include but are not limited to thin-film photovoltaic solar cells and photovoltaic detectors. In at least one embodiment, the present disclosure includes a solar cell comprising a material of self-assembled PbS QDs embedded within a PbS micro-crystal matrix having increased short circuit current density (J_{sc}). In one non-limiting embodiment, a J_{sc} of 47.5 mA/cm² is achieved with such nanocrystal/microcrystal PbS/CdS solar cell. In at least one embodiment, the present disclosure thus includes a solar cell with PbS QDs embedded in a PbS bulk material matrix. In at least one embodiment, the present disclosure includes a solar cell with PbSe QDs embedded in a PbSe bulk material matrix. The embedded Pb-salt QDs and Pb-salt bulk material matrix may be grown simultaneously, for example by CBD. A bulk material matrix containing embedded QDs may be referred to herein as a quantum dot matrix (QDM) material.

Before describing various embodiments in more detail by way of exemplary description, examples, and results, it is to be understood that the present disclosure is not limited in application to the details of methods and compositions as set forth in the following description. The disclosure is capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the presently disclosed concepts may be practiced without these specific details. In other instances, features which are well known to persons of ordinary skill in the art have not been described in detail to avoid unnecessary complication of the description.

Unless otherwise defined herein, scientific and technical terms used herein shall have the meanings that are commonly understood by those having ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the present disclosure pertains. All patents, published patent applications, and non-patent publications referenced in any portion of this application are herein expressly incorporated by reference in their entirety to the same extent as if each individual patent or publication was specifically and individually indicated to be incorporated by reference. U.S. Published Patent Applications 20150325723 and 20160111579 are hereby incorporated by reference herein in their entireties.

All of the compositions and methods of production and application thereof disclosed herein can be made and executed without undue experimentation in light of the present disclosure. While the compositions and methods of the present disclosure have been described in terms of particular embodiments, it will be apparent to those of skill in the art that variations may be applied to the compositions and/or methods and in the steps or in the sequence of steps of the method described herein without departing from the concept, spirit and scope of the inventive concepts. All such similar substitutes and modifications apparent to those of skilled in the art are deemed to be within the spirit and scope of the inventive concepts disclosed herein.

As utilized in accordance with the methods and compositions of the present disclosure, the following terms, unless otherwise indicated, shall be understood to have the following meanings:

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 11, 12, 13, 14, 15, 16, 17, 18, 19, 20, 21, 22, 23, 24, 25, 30, 35, 40, 45, 50, 55, 60, 65, 70, 75, 80, 85, 90, 95, 100, or more, or any integer inclusive therein. The term “at least one” may extend up to 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. For example, unless otherwise noted, a process, method, article, or apparatus that comprises a list of elements is not necessarily limited to only those elements, but may also include elements not expressly listed or inherent to such process, method, article or apparatus.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the term “about” is used to indicate that a value includes the inherent variation of error for the composition, the method used to administer the composition, or the variation that exists among the study subjects. Further, in this detailed description and the appended claims, each numerical value (e.g., temperature or time) should be read once as modified by the term “about” (unless already expressly so modified), and then read again as not so modified unless otherwise indicated in context. For example but not by way of limitation, when the term “about” is utilized, the designated value may vary by plus or minus fifteen percent, plus or minus twelve percent, or plus or minus eleven percent, or plus or minus ten percent, or plus or minus nine percent, or plus or minus eight percent, or plus or minus seven percent, or plus or minus six percent, or plus or minus five percent, or plus or minus four percent, or plus or minus three percent, or plus or minus two percent, or plus or minus one percent, or plus or minus one-half percent.

Also, any range listed or described herein is intended to include, implicitly or explicitly, any number within the range, particularly all integers, including the end points, and is to be considered as having been so stated. For example, “a range from 1 to 10” is to be read as indicating each possible number, particularly integers, along the continuum between about 1 and about 10, including for example 2, 3, 4, 5, 6, 7, 8, and 9. Similarly, fractional amounts between any two consecutive integers are intended to be included herein, such as, but not limited to, 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, and 0.95. For example, the range 3 to 4 includes, but is not limited to, 3.05, 3.1, 3.15, 3.2, 3.25, 3.3, 3.35, 3.4, 3.45, 3.5, 3.55, 3.6, 3.65, 3.7, 3.75, 3.8, 3.85, 3.9, and 3.95.Thus, even if specific data points within the range, or even no data points within the range, are explicitly identified or specifically referred to, it is to be understood that any data points within the range are to be considered to have been specified, and that the inventors possessed knowledge of the entire range and the points within the range.

As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time, or comprises at least 90%, 95%, or 98% of the reference quantity.

Where used herein, the notation “IV-VI” refers to a semiconductor material constructed from at least one Group IVA element (e.g., Pb, Sn, Ge) and at least one Group VIA element (e.g., S, Se, Te). Where used herein, the notation “IIB-VI” is intended to refer to a semiconductor material comprising at least one Group IIB element (e.g., Cd, Zn) and at least one Group VIA element. “Pb-salt” refers to a compound comprising lead (e.g., PbSe). “Non-Pb-salt” refers to a compound absent lead (e.g., CdSe). The semiconductor material may comprise ternary or quaternary materials such as, for example, PbSe_{y}Te_{1-y}, PbSe_{y}S_{1-y}, and PbTe_{y}S_{1-y}, wherein 0≤y≤1, PbₓX₁₋ₓSe_{y}Te_{1-y}, PbₓX₁₋ₓSe_{y}S_{1-y}, and PbₓX₁₋ₓTe_{y}S_{1-y}, wherein X is Sn, Sr, Eu, Ge, or Cd, and wherein 0≤x≤1 and 0≤y≤1, or CdSe₁₋ₓSx, CdₓZn₁₋ₓSe_{y}S_{1-y}, wherein 0≤x≤1 and 0≤y≤1. For example, a Pb-salt material may comprise ternary compounds such as, but not limited to, PbSnSe, PbSnTe, PbSrSe, PbSrTe, PbEuSe, PbEuTe, PbCdSe, and PbCdTe, or quaternary compounds, such as, but not limited to, PbSnSeTe, PbSnSeS, and PbSnTeS. Both the nanoscale crystallites (nanocrystals) and bulk material matrix (e.g., monocrystalline or polycrystalline) of the structures of the present disclosure can be formed from the semiconductor materials listed herein.

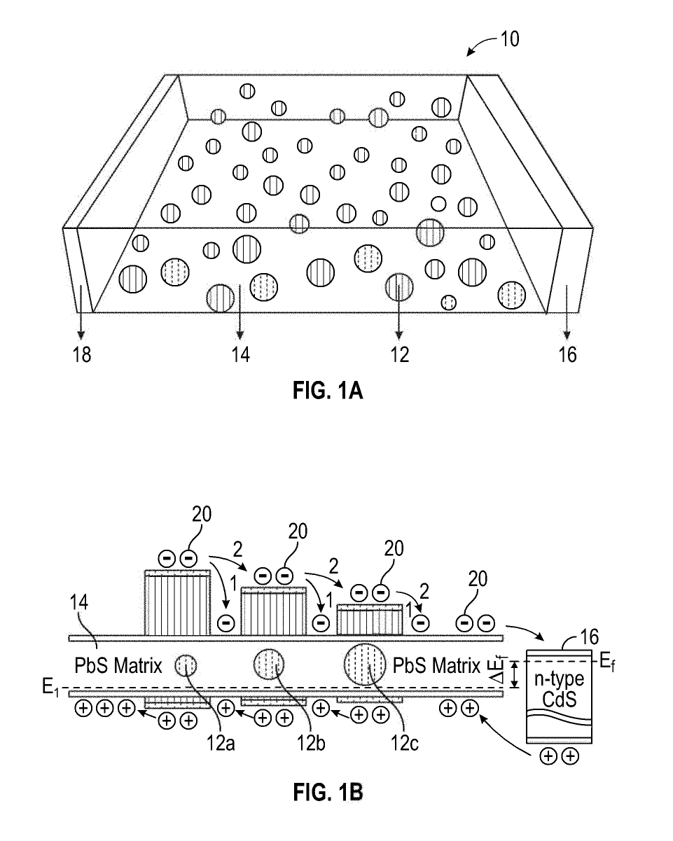

Referring now to the Figures, and in particular FIG. 1(a), shown therein is a structure 10 composed of QDs (i.e., nanoscale crystallites) 12 and a matrix material 14 between an n-type layer 16 and ohmic contact 18. In some embodiments, the structure 10 may be a two-band structure. The QDs 12 and matrix material 14 may have different band gap energies. Upon illumination, both QDs 12 and matrix material 14 of the structure 10 may be capable of absorbing light and generating photon-induced free carriers. The matrix material 14 may be a bulk micro-crystalline matrix, for example.

In some non-limiting embodiments, the QDs 12 of the structure 10 may have different sizes (i.e., may be inhomogeneous, or non-uniform in size). For example, in some embodiments, the size of one or more QDs 12 may be smaller than the Bohr radius of the semiconductor material comprising the QD. The structure 10 having different sized QDs 12 may provide a quantum effect. In some embodiments, such inhomogeneity of size of two or more QDs 12 may provide a broader absorption band as compared to a structure having same and/or similar sized QDs. Without wishing to be bound by theory, it is believed that excess carriers with higher potential in QDs 12 transport into the matrix material 14 in two possible ways. One way is similar to that in QD sensitized solar cells. Another is through possible threading conducting channels where the QDs 12 and the matrix material 14 may have the same or similar crystal orientation and the two interfaces happen to grow together.

FIG. 1(b) illustrates an exemplary embodiment of the structure 10 used in, for example, a p-n junction device. In this example, the bulk matrix material is p-type PbS and comprises a plurality of nanoscale crystallites (e.g., QDs) represented by QD 12a, QD 12b, and QD 12c, also comprising p-type PbS, which are embedded in the PbS bulk matrix material. The n-type layer 16 of the structure 10 comprises n-type CdS and with the p-type material may be used as an example of a PbS/CdS p-n junction device such as solar cell or detector. Although PbS and CdS are used in the example, it should be noted that the structures of the present disclosure include any material system including but not limited to materials such as IV-VI materials (e.g., PbSe, PbS, PbTe), II-VI materials (e.g., CdSe, CdS, CdTe), III-V material (e.g., GaAs, InP, GaSb), I-III-VI₂ semiconductor material (e.g. Copper indium gallium (di)selenide—CIGS etc.) and group IV materials (e.g., Si, Ge, etc.), or other materials as discussed elsewhere herein.

As is shown in FIG. 1(b), carriers 20 may travel from one QD 12 to another, especially from QDs small in size to QDs larger in size. For example, carriers 20 in FIG. 1(b) travel from the smallest QD 12a to the largest QD 12c. Further, carriers 20 may travel from one QD 12 to another when QDs are positioned close to each other in space. The majority of carriers 20 may transport in the matrix material 14. If the total film thickness is smaller than the size of the matrix material 14, the carriers 20 may transport to an electrode without crossing any additional boundary. As such, in some embodiments, carriers 20 may need only cross a single interface between QD 12 and the matrix material 14. This is in contrast to CQD films where carriers generally cross many interfaces, and may scatter or become trapped by interface defect states. Therefore, the carrier transport and increase efficiencies of such structures may be significantly improved in the structure 10. Because the absorption coefficient of QDs 12 may be significantly higher than that of the matrix material 14, most of the photon-induced carriers 20 could be generated by QDs, especially for thin films. Thus, the matrix material 14 in the structure 10 is configured to be a carrier transport channel, in addition, or in lieu of an absorber. It is not required that the nanoscale crystallites of the structures of the present disclosure have non-uniform sizes. Therefore in other embodiments of the present disclosure, the nanoscale crystallites of a particular structure may be substantially uniform in size and/or spatial distribution or substantially non-uniform in size and/or spatial distribution.

Determination of sizing for QDs 12 may be based on determined use. For example, in using the structure 10 as a detector, a cut-off wavelength may be determined by absorption edge of the QDs 12. In another example, in using the structure 10 in a solar cell, open circuit voltage (V_{oc}) may be determined by the Fermi-energy level difference of p-type matrix material and n-type material forming a p-n junction, as is shown in FIG. 1b. In certain embodiments, a narrow band gap matrix material such as PbS may limit the V_{oc} and thus the PCE. Other material systems with higher V_{oc} could offer more optimized PCE. Optimization of bandgaps for both QD 12 and matrix materials 14 may further improve PCE.

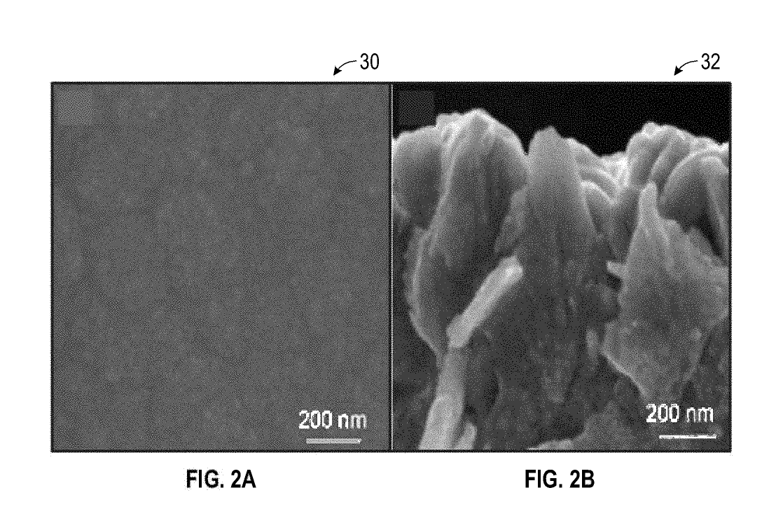

In some embodiments, solution based crystal growth methods, such as chemical bath deposition (CBD), can be used to create the structure 10. By controlling the solution temperature and by adding a chelating or nucleating agent (such as but not limited to TEA) in the growth process, the bulk crystal growth process may be suppressed, thereby encouraging formation of nanometer crystallites by a nucleation process. The size of the crystallites can be controlled in nanometer scale, thus forming self-assembled QDs 12. Under certain conditions when such nucleation process and crystal growth process occurs simultaneously, QDs 12 may be embedded in the micro-size-crystallite matrix, forming a structure as schematically-represented in FIGS. 1(a) and 1(b) and shown in FIG. 2(b). As one skilled in the art will appreciate, other growth methods for materials that enable both nucleation and crystal growth processes simultaneously, such as physical vapor deposition, may also be used. FIG. 1(a) illustrates a polycrystalline semiconductor with many inhomogeneously (non-uniformly)-sized nanoscale crystallites (QDs). In certain embodiments, the QDs are absent ligand-based interfaces that have boundary domains within a micro-size crystallite.

With illumination, both QDs 12 and matrix materials 14, each having different band gap energies, may absorb light and generate photon-induced free carriers 20. In the structure 10, inhomogeneity of size in QDs 12 may provide a broad multiband absorption. Excess carriers 20 with higher potential in QDs 12 transport into the matrix material 14 in a manner similar to that in QD sensitized solar cells²²⁻²³ or via threading conducting channels (e.g., PbS QD and PbS matrix having the same crystal orientation such that the two interfaces happen to grow together). Carriers 20 hopping from one QD 12 to another especially from small QD to larger QD (e.g., from QD 12a to QD 12b) is also possible when QDs 12 are close enough in space. When the total film thickness is smaller than the size of the material matrix 14, the carriers 20 may transport to an electrode without crossing any additional boundary, in contrast to CQD films where carriers have to cross many interfaces and thus become scattered or trapped by interface defect states.

Open circuit voltage (V_{oc}) may be determined by the Fermi-energy level difference of the p-type matrix material 14 and the n-type material 16 that forms p-n junction, as shown in FIG. 1(b). Therefore, a small band gap matrix material 14 such as PbS may limit the V_{oc}, and thus the PCE. Other material systems with higher V_{oc} can offer more optimized PCE. In one non-limiting example, the structure may comprise p-type PbS QDs 12 formed in situ in bulk micro-scale PbS matrix material 14.

Materials and Methods

In one non-limiting example of fabrication of a solar cell, a CdS thin film with 200 nm in thickness was grown in an aqueous solution at 60° C.²⁰ A mixed aqueous solution with 0.072 mol/L cadmium nitrate (Cd(NO₃)₂) and 0.072 mol/L ammonium nitrate (NH₄NO₃) was used as Cd precursor, while a 0.144 mol/L thiourea (CH₄N₂S) was used as S precursor. The two equivalent volume solutions (20 ml) were mixed together in another 60 ml glass bottle and 10 ml ammonium hydroxide (NH₃.H₂O, 28-30%) was introduced into the bottle to adjust pH of the precursor. The cleaned FTO substrates were immersed upside down into the aqueous precursor and maintained at 70° C. for 1.0 h. After the growth, the as-grown CdS samples were rinsed in deionized water and then purged to dry out under nitrogen (N₂). Finally, the CdS films were annealed at a temperature range between 100° C. and 450° C. for 1-60 min in N₂ atmosphere. Structures of the present disclosure may be grown or constructed on any suitable substrate material. For example, the substrate may include, but is not limited to: a silicon substrate, such as a monocrystalline silicon substrate; a silicon micro-lens; a mid-infrared transparent substrate; an infrared transparent substrate; a substrate transparent to light in a visible portion of the light spectrum; a polyimide substrate developed for solar cell applications; a monocrystalline semiconductor material; or other monocrystalline or polycrystalline substrates. The substrate can be constructed of a monocrystalline or polycrystalline material such as, but not limited to, Si (e.g., monocrystalline silicon), glass, silica, SiO₂, quartz, sapphire, CaF₂, and conductive transparent (in visible) materials such as fluorine doped Tin Oxide, or Indium Tin Oxide.

Subsequently, PbS QD and QDM films were face-down grown on the CdS film in a precursor solution containing 45 mM lead nitrate (Pb(NO₃)₂), 33 mM TEA, 260 mM potassium hydroxide (KOH) and 55 mM CH₄N₂S at 4° C. and room temperature, respectively. For this experiment, the growth time of 12 hour and 1 hour were carried out for PbS QD films and PbS QDM films, respectively.

For the solar cell devices, a small segment of the PbS/CdS film on one of the edges was wet-chemical etched by using 10% hydrochloric HCl to explore Fluorine doped Tin Oxide (FTO) layer. A negative photoresist (AZ nL of 2020) layer was coated onto PbS/CdS film with naked FTO substrates by spin-coating at 4500 rpm for 60 seconds, followed by a soft bake for 2.5 minutes at 110° C. Then, square-hole photoresist arrays were patterned by using UV lithography (275 W) with an exposure time of 10 seconds, followed by a hard bake for 3 minutes and a development time of 45 seconds. Subsequently, 100 nm thick Au film was deposited on the photoresist pattern by employing evaporation at room temperature for 30 minutes in 2×10⁻⁴ Pa. Finally, Au electrode pattern was obtained after lift off in acetone solvent for 5 minutes.

The top and cross-sectional morphology of the CdS/PbS solar cells were examined by a Zeiss Neon-40 EsB high resolution field-emission scanning electron microscope (FESEM). Hall effect measurements were conducted in Van der Pauw four-point probe configuration, using fresh indium contacts, in an automated EGK HEM-2000, with a magnetic induction of 0.37 T. The visible-NIR PL spectrum was conducted by Princeton Instruments acton sp2500 monochromater with 325 nm He—Cd laser, while the MIR PL spectrum were characterized by a Fourier transform infrared (FTIR) spectrometer in Step-Scan mode with a 1.064 um Q-switched Nd:YAG pumping laser (5 ns, 10 Hz). The Current density-voltage (J-V) behavior was examined by using a current-voltage analyzer and a solar simulator (Oriel Sol2A Solar simulator) under AM 1.5 G.

CBD Growth of PbS QDs Simultaneously Embedded in Micro-PbS Matrix.

In a non-limiting example of the construction of a structure of the present disclosure, PbS films were grown by CBD method. By controlling the growth temperature between 0° C. and 100° C., and by adding chelating agent in the solution (such as triethanolamine C₆H₁₅NO₃—TEA), the bulk crystal growth process could be suppressed, encouraging formation of nano-scale crystallites by nucleation process. The size of the crystallites can be controlled in nanometer scale thus forming self-assembled QDs. The lead ions Pb²⁺ provided by lead nitrate are chelated by TEA, which releases free lead ions as lead source. Then the free lead ions react with thiourea to form PbS nucleation in the strong base medium. The PbS nucleation is determined by the release rate of the free lead ions when fixing the thiourea to lead molar ratio (1:1). The slow release rate of the free lead ions in the solution leads to the PbS nucleation, but less growth subsequently, while the high release rate of the free lead ions enables PbS nucleation as well as the growth. At 4° C. with 1.5 mL TEA, since PbS nucleation process dominates PbS, a film substantially comprising QDs is formed. At room temperature and/or with lower (or no) concentration of TEA, a film substantially comprising only micro-size polycrystalline PbS (the bulk matrix material) is formed. However, when the growth conditions are in-between those that promote the micro-crystallite growth and QD crystallite growth, both QDs and micro-size crystal form simultaneously, creating PbS QDs embedded in micro-size bulk PbS crystallites, in accordance with the inventive concepts of the present disclosure.

FIGS. 2(a) and 2(b) show SEM images of two typical types of CBD PbS with QD structures. FIG. 2(a) shows top morphology of a PbS QD sample 30. In this type of sample 30, the entire film comprises QDs grouped in different domains of a couple of hundred nm in size. FIG. 2(b) shows a cross sectional image of a sample 32 in which the density of PbS QDs is reduced and PbS QDs are embedded in PbS micro-crystallite matrix (bulk material matrix). For purpose of simplicity herein, these two types of samples are referred to as QD and QDM, respectively. Both types of films have densely packed nano-/micro-structure without voids. The EDX analysis shows the Pb:S molar ratio is 51.9: 48.1 without oxygen trace.

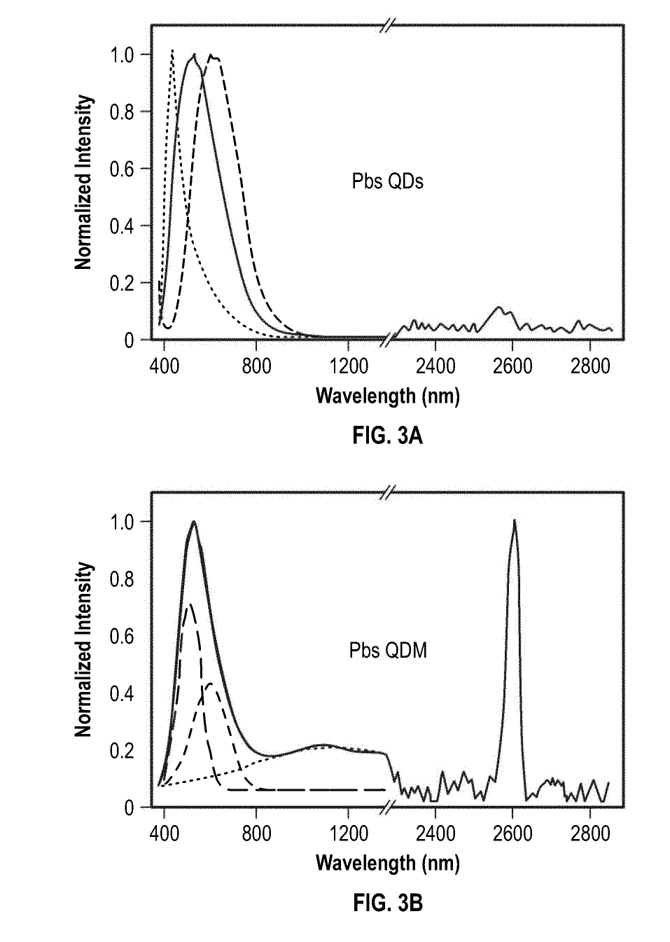

Referring to FIGS. 3(a) and 3(b), the structure 10 may be further characterized by photoluminescence (PL) emission and transmission spectra. FIGS. 3(a) and 3(b) show photoluminescence (PL) emission spectra of three 150 nm thick PbS QD films (shown in FIG. 3(a)) and a 400 nm thick PbS QDM film grown on glass (shown in FIG. 3(b)). For QD film samples shown in FIG. 3(a) only one broad PL emission peak in 0.4-0.8 μm range was observed indicating a vast majority of the film consisted of nano-scaled QDs. PL emissions of all QD films are very similar in the mid-infrared range, and as such, only one PL spectrum is shown in FIG. 3(a). Additionally, FIG. 3(a) illustrates a very weak emission peak with intensity close to the noise level around 2.56 μm.

For the QDM sample, as shown in FIG. 3(b), three PL emission peaks were observed including a strong emission peak at 2.62 μm, a weak broad emission peak around 1.15 μm, and a peak at 0.52 μm similar to the PL emission peak in QD. The 2.62 μm emission peak may be due to PbS micro-crystal, and the blue-shift compared to PbS bulk energy bandgap to Burstein-Moss effect²⁷ and possible oxidation at the grain boundaries of the micro-size PbS crystallites.

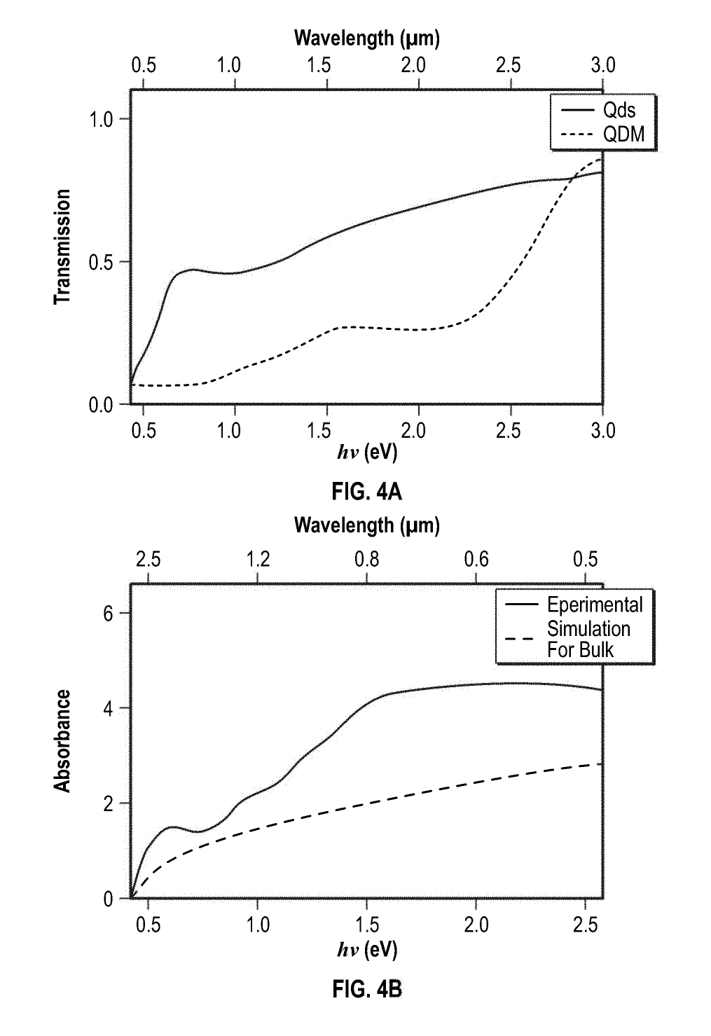

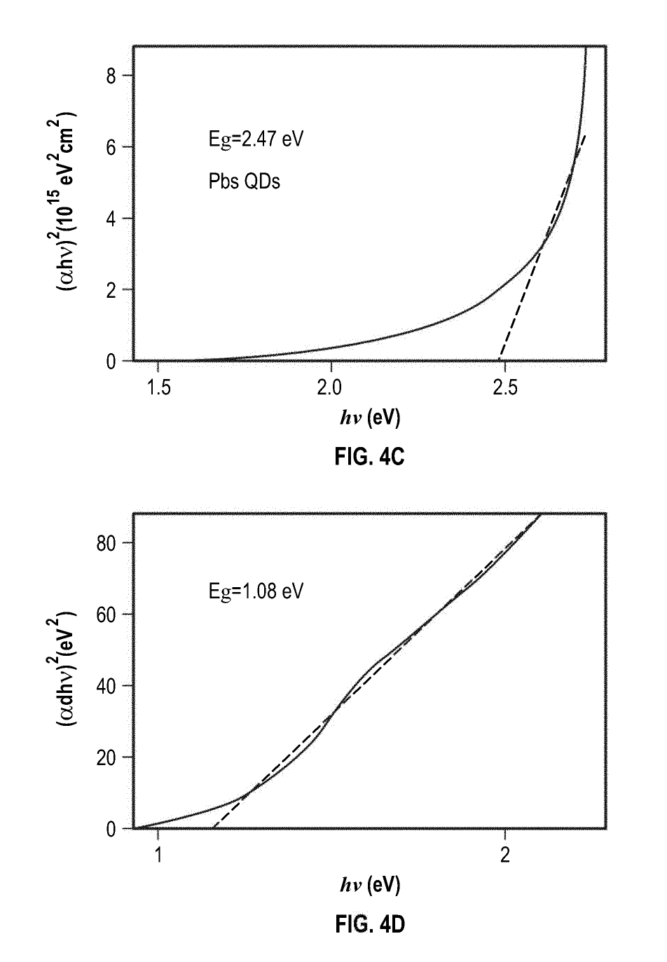

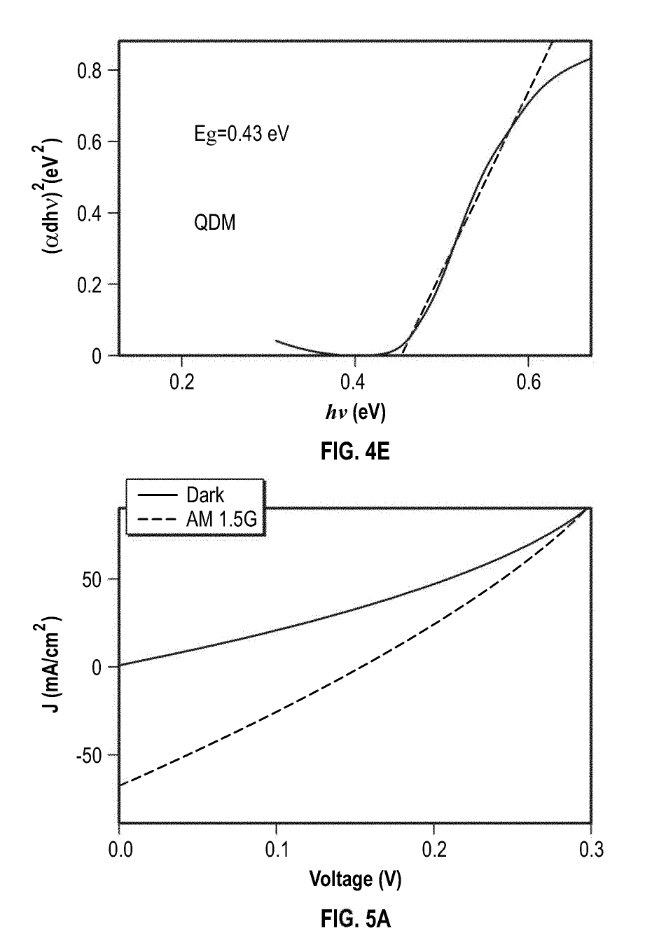

Transmission measurements were performed on all samples. All QD samples show similar transmission spectra. For simplicity purpose to compare QD and QDM samples, QD sample with PL emission peak around 0.51 μm was shown together with the QDM sample in FIG. 4(a).

FIG. 4(b) indicates both PbS QDs and micro-crystal PbS may coexist. Since EDX analysis only shows PbS, the PL emissions in the shorter wavelength may be from PbS QD emissions. The broad emission peaks from QDs both in QD and QDM samples indicate inhomogeneous QD size distribution. The broad emission peak at 0.52 μm may include two emissions at 0.50 μm and 0.60 μm. The weaker broad emission peak around 1.15 μm could be from QDs with inhomogeneous sizes.

In the example, the thickness of PbS QD and PbS QDM sample is about 150 nm and about 400 nm, respectively, both grown on glass substrates. As can be seen, PbS QD sample shows only one strong absorption edge, whose optical band gap is calculated to be 2.47 eV (illustrated in FIG. 4(c)) which agrees with PL emission peak (mid curve in FIG. 3(a)). The PbS QDM sample, however, show two absorption edges, as shown in FIGS. 4(d) and 4(e). The band gap of 0.43 eV is very close to the bulk PbS band gap (0.41 eV), indicating micro-size PbS matrix in the film. Another absorption band gap of 1.08 eV is derived, which most likely indicates statistical average absorption of the QDs that contribute to the PL emission around 1.15 μm shown in FIG. 3(b). Higher absorption band around 0.52 μm as indicated in the PL emission spectra could not be derived from the transmission spectra as the transmission is already very low at wavelength shorter than about 1 μm. Due to the QDs in matrix structure the actual thicknesses of different PbS QDs and micro-PbS matrix are unknown. Therefore, ad (absorption coefficient times thickness) may be used instead of only a in the simulation for QDM sample as shown in FIGS. 4(d) and 4(e). To compare the total absorption of the PbS QDM sample with PbS bulk material, the bulk PbS absorbance is simulated based on reference²⁸. As can be seen, the PbS QDM absorption becomes significantly higher than that of bulk PbS in optical energies higher than about 1 eV due to QD absorption. Although the micro-PbS matrix may have much larger material volume than QDs in the QDM sample, the QD absorptions contribute about the same as the micro-PbS matrix. This is because the absorption coefficient of QD PbS may be about 10 times higher than that of bulk PbS.²⁸⁻³⁰ Room temperature Hall measurements show that all samples are p-type. Table 1 lists the measured Hall hole concentration and Hall mobility. The hole concentrations are about the same. The QD PbS film has lower mobility than that of PbS QDM film. As such, Hall mobility may be affected by the carrier scattering mechanism at the boundaries of nano-/micro-crystallites.

TABLE 1
Hall measurement for PbS films

| | Hole | |
|---|---|---|
| | concentration | Mobility |
| CBD film | (×10¹⁸/cm³) | (cm²/V · s) |
| QD film | 2.25 | 1.7 |
| QDM film | 1.78 | 16.05 |

Performance of the QDM Solar Cells.

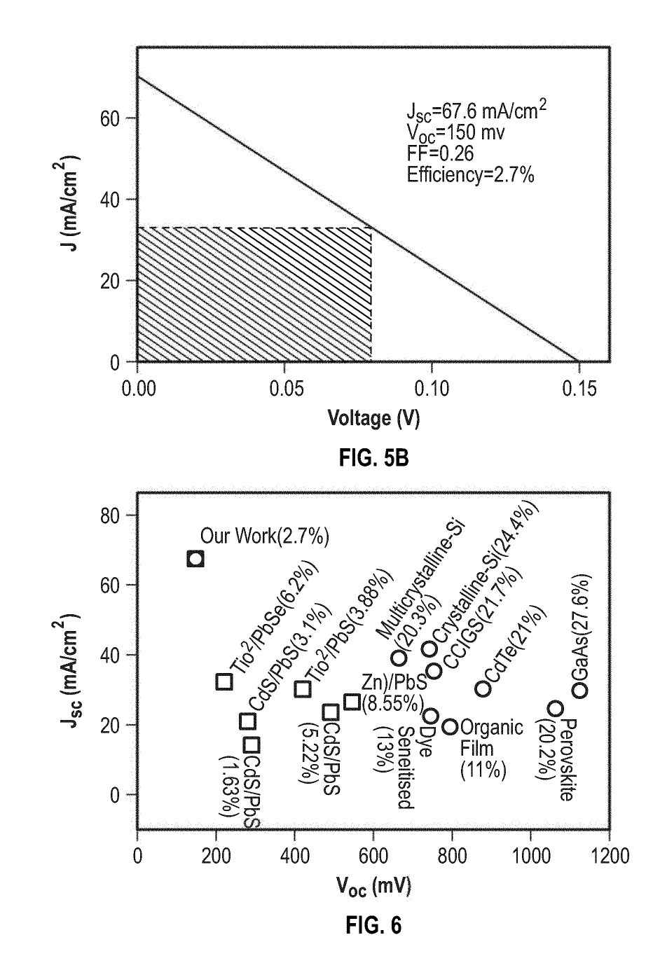

n-CdS/p-PbS heterojunction solar cells with both PbS QDM film and PbS QD film were fabricated on fluoride-doped tin dioxide (FTO) glass by two-step CBD. For the several samples made with PbS QD solar cells in accordance with the present disclosure, typical V_{oc} is about 350-450 mV, but typical J_{sc} is only 3-4 mA.cm⁻², resulting in typical PCE less than 1%. For PbS QDM solar cell sample, however, Jsc may be significantly increased. FIGS. 5(a) and 5(b) show the measured J-V (current density vs. voltage) curves for a 600 nm PbS QDM sample under the same growth condition of the QDM sample shown in previous measurements.

In comparison with the PbS QD solar cells, V_{oc} of PbS QDM solar cell decreases to 150 mV. However, J_{sc} increases to 67.6 mA.cm⁻², which is about 20 times higher than that of prior art QD solar cells. Calculated PCE is 2.7%. FIG. 6 (a J_{sc}-V_{oc} map for the typical photovoltaic solar cells^{9, 10, 13, 17, 31-42}) shows the relative standing in different solar cell materials excluding multi junction solar cells, based on a literature search. The highlighted J_{sc} illustrates the use of the structure 10 in a solar cell may improve carrier extraction. Further improvement of PCE using such structure 10 may include using a different material system to increase V_{oc}. This together with an n-type material with smaller electronic affinity (e.g. ZnO or TiO2) could increase V_{oc}.

In summary, the present disclosure includes, in at least some embodiments, material structures constructed of quantum dots embedded in a crystalline bulk material matrix of the same chemical composition as the quantum dots. In one non-limiting example, structures may be grown by CBD. The structures can be used for example in photovoltaic devices such as solar cells and in photodetectors. Materials for formation of the structure 10 may include, but are not limited to, IV-VI materials (e.g., PbSe, PbS, PbTe), II-VI materials (e.g., CdSe, CdS, CdTe), III-V material (e.g., GaAs, InP, GaSb), I-III-VI₂ semiconductor material (e.g., copper indium gallium (di)selenide—CIGS), and group IV materials (e.g., Si, Ge, etc.).

In at least certain embodiments, the present disclosure is directed to a structure comprising a bulk crystalline matrix material; and a plurality of nanoscale crystallites embedded within the bulk crystalline matrix material, wherein the bulk crystalline matrix material and the nanoscale crystallites comprise a semiconductor material having the same chemical composition, and wherein the nanoscale crystallites are spatially distributed throughout substantially the entire bulk crystalline matrix material. The bulk crystalline matrix material and the nanoscale crystallites may comprise a IV-VI semiconductor material. The IV-VI semiconductor material may be selected from the group consisting of PbSe, PbS, and PbTe. The bulk crystalline matrix material and the nanoscale crystallites may comprise a II-VI semiconductor material. The II-VI semiconductor material may be selected from the group consisting of CdSe, CdS, and CdTe. The bulk crystalline matrix material and the nanoscale crystallites may comprise a III-V semiconductor material. The III-V semiconductor material may be selected from the group consisting of GaAs, InP, and GaSb. The bulk crystalline matrix material and the nanoscale crystallites may comprise a I-III-VI₂ semiconductor material. The I-III-VI₂ semiconductor material may be copper indium gallium (di)selenide (CIGS). The nanoscale crystallites of the structure may be absent ligand-based interfaces. The size of one or more of the nanoscale crystallites may be less than the Bohr radius of the semiconductor material comprising the at least one nanoscale crystallite. A first absorption coefficient of the plurality of nanoscale crystallites may be more than a second absorption coefficient of the bulk crystalline matrix material. The plurality of nanoscale crystallites may comprises a first quantum dot having a first absorption band and a second quantum dot having a second absorption band different than the first absorption band. The semiconductor material of the bulk crystalline matrix material and the nanoscale crystallites may be a p-type semiconductor material, and may optionally be disposed on an n-type semiconductor material. The p-type semiconductor material may be a IV-VI material, and the n-type semiconductor material may be a II-VI material. The p-type semiconductor material may be PbS or PbSe, and the n-type semiconductor material may be CdS. The semiconductor material of the bulk crystalline matrix material and the nanoscale crystallites may be an n-type semiconductor material, and may optionally be disposed on a p-type semiconductor material. The nanoscale crystallites of the structure may be quantum dots. In further embodiments, the structure may comprise a component of a solar cell or a photodetector. The solar cell may have a short-circuit current density (J_{sc}) of at least of 47.5 mA/cm². In another embodiment, the present disclosure is directed to a method of forming a semiconductor structure comprising, providing a semiconductor material precursor solution comprising a nucleating agent; and applying the semiconductor material precursor solution to a surface under conditions suitable for growth of a bulk crystalline matrix material on the surface and for causing formation of a plurality of nanoscale crystallites within the bulk crystalline matrix material, wherein the bulk crystalline matrix material and the nanoscale crystallites comprise the same chemical composition, and wherein the nanoscale crystallites are embedded and spatially distributed throughout substantially the entire bulk crystalline matrix material.

It will be understood from the foregoing description that various modifications and changes may be made in the various embodiments of the present disclosure without departing from their true spirit. Similarly, changes may be made in the formulation of the various components and compositions described herein, the methods described herein or in the steps or the sequence of steps of the methods described herein without departing from the spirit and scope of the present disclosure. The description provided herein is intended for purposes of illustration only and is not intended to be construed in a limiting sense. Thus, while the present disclosure has been described herein in connection with certain embodiments so that aspects thereof may be more fully understood and appreciated, it is not intended that the present disclosure be limited to these particular embodiments. On the contrary, it is intended that all alternatives, modifications and equivalents are included within the scope of the inventive concepts as defined herein. Thus the examples described above, which include particular embodiments, will serve to illustrate the practice of the present disclosure, it being understood that the particulars shown are by way of example and for purposes of illustrative discussion of particular embodiments only and are presented in the cause of providing what is believed to be a useful and readily understood description of procedures as well as of the principles and conceptual aspects of the inventive concepts.

### REFERENCES

[1] Ellingson, R. J.; Beard, M. C.; Johnson, J. C.; Yu, P.; Micic, O. I.; Nozik, A. J.; Shabaev, A.; Efros, A. L. Nano Lett. 2005, 5, 865-871.
[2] Kamat, P. V. J. Phys. Chem. C 2008, 112, 18737-18753.
[3] Ma, W.; Luther, J. M.; Zheng, H.; Wu, Y.; Alivisatos, A. P. Nano Lett. 2009, 9, 1699-1703
[4] Leschkies, K. S.; Beatty, T. J.; Kang, M. S.; Norris, D. J.; Aydil, E. S. ACS Nano 2009, 3, 3638-3648.
[5] Zhao, N.; Osedach, T. P.; Chang, L.-Y.; Geyer, S. M.; Wanger, D.; Binda, M. T.; Arango, A. C.; Bawendi, M. G.; Bulovic, V. ACS Nano 2010, 4, 3743-3752.
[6] Milliron, D. J. Nat. Mater. 2014, 13, 772-773.
[7] Carey, G. H.; Abdelhady, A. L.; Ning, Z.; Thon, S. M.; Bakr, O. M.; Sargent, E. H. Chem. Rev. 2015, ASAP paper.
[8] Semonin, O. E.; Luther, J. M.; Choi, S.; Chen, H.-Y.; Gao, J.; Nozik, A. J.; Beard, M. C. Science 2011, 334, 1530-1533.
[9] Chuang, C.-H. M.; Brown, P. R.; Bulovi' c, V.; Bawendi, M. G. Nat. Mater. 2014, 13, 796-801.
[10] Zhang, J.; Gao, J.; Church, C. P.; Miller, E. M.; Luther, J. M.; Klimov, V. I.; Beard, M. C. Nano Lett. 2014, 14, 6010-6015.
[11] Lee, M. M.; Teuscher, J.; Miyasaka, T.; Murakami, T. N.; Snaith, H. J. Science 2012, 338, 643-647.
[12] Burschka, J.; Pellet, N.; Moon, S.-J.; Humphry-Baker, R.; Gao, P.; Nazeeruddin, M. K.; Grätzel, M. Nature 2013, 499, 316-319.
[13] Yang, W. S.; Noh, J. H.; Jeon, N. J.; Kim, Y. C.; Ryu, S.; Seo, J.; Seok, S. I. Science 2015, 348, 1234-1237.
[14] Hillhouse, H. W.; Beard, M. C. Curr. Opin. Colloid Interface Sci. 2009, 14, 245-259.
[15] Garcia-Valenzuela, J.; Baez-Gaxiola, M.; Sotelo-Lerma, M. Thin Solid Films 2013, 534, 126-131.
[16] Seghaier, S.; Kamoun, N.; Brini, R.; Amara, A. Mater. Chem. Phys. 2006, 97, 71-80.
[17] Yeon, D. H.; Lee, S. M.; Jo, Y. H.; Moon, J.; Cho, Y. S. J. Phys. Chem. A 2014, 2, 20112-20117.
[18] Tang, J.; Sargent, E. H. Adv. Mater. 2011, 23, 12-29.
[19] Qiu, J.; Weng, B.; Yuan, Z.; Shi, Z. J. Appl. Phys. 2013, 113, 103102.
[20] Weng, B.; Qiu, J.; Zhao, L.; Chang, C.; Shi, Z. Appl. Phys. Lett. 2014, 104, 121111.
[21] Zhao, L.; Qiu, J.; Weng, B.; Chang, C.; Yuan, Z.; Shi, Z. J. Appl. Phys. 2014, 115, 084502.
[22] Zídek, K.; Zheng, K.; Abdellah, M.; Lenngren, N.; Chabera, P.; Pullerits, T. Nano Lett. 2012, 12, 6393-6399.
[23] Tvrdy, K.; Frantsuzov, P. A.; Kamat, P. V. Proc. Natl. Acad. Sci. U.S.A. 2011, 108, 29-34.
[24] López, N.; Reichertz, L.; Yu, K.; Campman, K.; Walukiewicz, W. Phys. Rev. Lett. 2011, 106, 028701.
[25] Nozik, A. J.; Beard, M. C.; Luther, J. M.; Law, M.; Ellingson, R. J.; Johnson, J. C. Chem. Rev. 2010, 110, 6873-6890.
[26] Sogabe, T.; Shoji, Y.; Ohba, M.; Yoshida, K.; Tamaki, R.; Hong, H.-F.; Wu, C.-H.; Kuo, C.-T.; Tomi' c S.; Okada, Y. Sci. Rep. 2014, 4, 4792.
[27] Schubert, E. F. Doping in III-V semiconductors; Cambridge University Press, 2005; Vol. 1.12
[28] Schoolar, R.; Dixon, J. Phys. Rev. 1965, 137, A667.
[29] Moreels, I.; Lambert, K.; Smeets, D.; De Muynck, D.; Nollet, T.; Martins, J. C.; Vanhaecke, F.; Vantomme, A.; Delerue, C.; Allan, G. ACS Nano 2009, 3, 3023-3030.
[30] Wakaki, M.; Shibuya, T.; Kudo, K. Physical properties and data of optical materials; CRC Press, 2007.
[31] Hernández-Borja, J.; Vorobiev, Y.; Ramírez-Bon, R. Sol. Energ. Mat. Sol. Cells 2011, 95, 1882-1888.
[32] Yao, X.; Chang, Y.; Li, G.; Mi, L.; Liu, S.; Wang, H.; Yu, Y.; Jiang, Y. Sol. Energ. Mat. Sol. Cells 2015, 137, 287-292.
[33] Abbas, M. A.; Basit, M. A.; Park, T. J.; Bang, J. H. Phys. Chem. Chem. Phys. 2015, 17, 9752-9760.
[34] Lee, J.-W.; Son, D.-Y.; Ahn, T. K.; Shin, H.-W.; Kim, I. Y.; Hwang, S.-J.; Ko, M. J.; Sul, S.; Han, H.; Park, N.-G. Sci. Rep. 2013, 3, 1050.
[35] Zhang, X.; Zhang, Y.; Yan, L.; Ji, C.; Wu, H.; Wang, Y.; Wang, P.; Zhang, T.; Wang, Y.; Cui, T. J. Mater. Chem. A 2015, 3, 8501-8507.
[36] Zhao, J.; Wang, A.; Green, M. A.; Ferrazza, F. Appl. Phys. Lett. 1998, 73, 1991-1993.
[37] Schultz, O.; Glunz, S.; Willeke, G. Progress in Photovoltaics: Research and Applications 2004, 12, 553-558.
[38] Jackson, P.; Hariskos, D.; Wuerz, R.; Kiowski, O.; Bauer, A.; Friedlmeier, T. M.; Powalla, M. Phys. Status Solidi Rapid Res. Lett. 2014, 9, 28-31.
[39] Green, M. A.; Emery, K.; Hishikawa, Y.; Warta, W.; Dunlop, E. D. Progress in photovoltaics: research and applications 2015, 23, 1-9.
[40] Kayes, B. M.; Nie, H.; Twist, R.; Spruytte, S. G.; Reinhardt, F.; Kizilyalli, I. C.; Higashi, G. S. 27.6% Conversion efficiency, a new record for single-junction solar cells under 1 sun illumination. 2011.
[41] Yella, A.; Lee, H.-W.; Tsao, H. N.; Yi, C.; Chandiran, A. K.; Nazeeruddin, M. K.; Diau, E. W.-G.; Yeh, C.-Y.; Zakeeruddin, S. M.; Grätzel, M. Science 2011, 334, 629-634.
[42] Hosoya, M.; Oooka, H.; Nakao, H.; Mori, S.; Gotanda, T.; Shida, N.; Saito, M.; Nakano, Y.; Todori, K.; Center, C. R. Module development for polymer solar cells. 2014.

1. A structure comprising:
a bulk crystalline matrix material; and
a plurality of nanoscale crystallites embedded within the bulk crystalline matrix material, wherein the bulk crystalline matrix material and the nanoscale crystallites comprise a semiconductor material having the same chemical composition, and wherein the nanoscale crystallites are spatially distributed throughout substantially the entire bulk crystalline matrix material.

2. The structure of claim 1, wherein the bulk crystalline matrix material and the nanoscale crystallites comprise a IV-VI semiconductor material.

3. The structure of claim 2, wherein the IV-VI semiconductor material is selected from the group consisting of PbSe, PbS, and PbTe.

4. The structure of claim 1, wherein the bulk crystalline matrix material and the nanoscale crystallites comprise a II-VI semiconductor material.

5. The structure of claim 4, wherein the II-VI semiconductor material is selected from the group consisting of CdSe, CdS, and CdTe.

6. The structure of claim 1, wherein the bulk crystalline matrix material and the nanoscale crystallites comprise a III-V semiconductor material.

7. The structure of claim 6, wherein the III-V semiconductor material is selected from the group consisting of GaAs, InP, and GaSb.

8. The structure of claim 1, wherein the bulk crystalline matrix material and the nanoscale crystallites comprise a I-III-VI₂ semiconductor material.

9. The structure of claim 8, wherein the I-III-VI₂ semiconductor material is copper indium gallium (di)selenide (CIGS).

10. The structure of claim 1, wherein the nanoscale crystallites are absent ligand-based interfaces.

11. The structure of claim 1, wherein size of at least one of the nanoscale crystallites is less than the Bohr radius of the semiconductor material comprising the at least one nanoscale crystallite.

12. The structure of claim 1, wherein a first absorption coefficient of the plurality of nanoscale crystallites is more than a second absorption coefficient of the bulk crystalline matrix material.

13. The structure of claim 1, wherein the plurality of nanoscale crystallites comprises a first quantum dot having a first absorption band and a second quantum dot having a second absorption band different than the first absorption band.

14. The structure of claim 1, wherein the semiconductor material of the bulk crystalline matrix material and the nanoscale crystallites is a p-type semiconductor material.

15. The structure of claim 14, disposed upon an n-type semiconductor material.

16. The structure of claim 15, wherein the p-type semiconductor material is a IV-VI material, and the n-type semiconductor material is a II-VI material.

17. The structure of claim 16, wherein the p-type semiconductor material is PbS or PbSe, and the n-type semiconductor material is CdS.

18. The structure of claim 1, wherein the semiconductor material of the bulk crystalline matrix material and the nanoscale crystallites is an n-type semiconductor material.

19. The structure of claim 18, disposed upon a p-type semiconductor material.

20. The structure of claim 1, wherein the nanoscale crystallites are quantum dots.

21. A solar cell comprising a structure comprising:
a bulk crystalline matrix material, and
a plurality of nanoscale crystallites embedded within the bulk crystalline matrix material, wherein the bulk crystalline matrix material and the nanoscale crystallites comprise a semiconductor material having the same chemical composition, and wherein the nanoscale crystallites are spatially distributed throughout substantially the entire bulk crystalline matrix material.

22. The solar cell of claim 21, having a short-circuit current density (J_{sc}) of at least of 47.5 mA/cm².

23. A photodetector comprising a structure comprising:
a bulk crystalline matrix material, and
a plurality of nanoscale crystallites embedded within the bulk crystalline matrix material, wherein the bulk crystalline matrix material and the nanoscale crystallites comprise a semiconductor material having the same chemical composition, and wherein the nanoscale crystallites are spatially distributed throughout substantially the entire bulk crystalline matrix material.

24-37. (canceled)
